(19) United States
(12) Patent Application Publication
(10) Pub. No.: US 2026/0095018 A1
(43) Pub. Date: Apr. 2, 2026

(54) SEMICONDUCTOR LASER ELEMENT

(71) Applicant: NICHIA CORPORATION, Anan-shi (JP)

(72) Inventor: Yusuke AOKI, Anan-shi (JP)

(73) Assignee: NICHIA CORPORATION, Anan-shi (JP)

(21) Appl. No.: 19/343,044

(22) Filed: Sep. 29, 2025

(30) Foreign Application Priority Data
Sep. 30, 2024 (JP) 2024-171290
Sep. 25, 2025 (JP) 2025-159404

(51) Int. Cl. H01S 5/02257; H01S 5/343

(52) U.S. Cl. CPC H01S 5/02257; H01S 5/343

(57) ABSTRACT

A semiconductor laser element includes a first semiconductor layer being a III-V compound semiconductor layer containing at least As; a second semiconductor layer located above the first semiconductor layer and being a III-V compound semiconductor layer containing at least P; a third semiconductor layer located above the second semiconductor layer; an active layer on the second semiconductor layer; a window structure formed across the first to third semiconductor layers and the active layer; a defect layer having a defect, located in a region where the window structure is formed and between the first and second semiconductor layers, and containing a group III element of each of the first and second semiconductor layers; and an end surface emitting laser light and including the defect layer. The defect layer does not overlap with a near-field pattern of laser light at the end surface or overlaps only with a tail of the near-field pattern.

### CROSS REFERENCE TO RELATED APPLICATION

This application claims priority to Japanese Patent Applications No. 2024-171290, filed on Sep. 30, 2024, and Japanese Patent Applications No. 2025-159404, filed on Sep. 25, 2025, the entire contents of which are hereby incorporated by reference.

### BACKGROUND

The present disclosure relates to a semiconductor laser element.

A semiconductor laser element that emits red or infrared laser light may be formed with a window structure on laser light emission end surface to improve resistance to catastrophic optical damage (COD). Japanese Patent Publication No. 2024-010144 discloses a semiconductor laser element having a window structure.

### SUMMARY

Even when a window structure is formed, generation of COD during driving of the semiconductor laser element may cause sudden death of the element.

An object of an embodiment of the present disclosure is to provide a semiconductor laser element whose sudden death caused by COD is reduced.

According to one embodiment of the present disclosure, a semiconductor laser element comprises: a first semiconductor layer that is a III-V group compound semiconductor layer containing at least As as a group V element; a second semiconductor layer of a first conductivity type side located above the first semiconductor layer, the second semiconductor layer being a III-V compound semiconductor layer containing at least P as a group V element; a third semiconductor layer of a second conductivity type side located above the second semiconductor layer; an active layer disposed between the second semiconductor layer and the third semiconductor layer; a window structure formed across the third semiconductor layer, the active layer, the second semiconductor layer, and the first semiconductor layer; a defect layer comprising a defect, the defect layer being located in a region in which the window structure is formed and between the first semiconductor layer and the second semiconductor layer, the defect layer containing a group III element of the first semiconductor layer and a group III element of the second semiconductor layer; and an end surface emitting a laser light, the end surface comprising a surface of the defect layer. The defect layer does not overlap with a near-field pattern of the laser light at the end surface, or overlaps only with a tail of the near-field pattern at the end surface.

According to one embodiment of the present disclosure, a semiconductor laser element comprising: a first semiconductor layer that is a III-V group compound semiconductor layer containing at least As as a group V element; a second semiconductor layer of a first conductivity type side located above the first semiconductor layer, the second semiconductor layer being a III-V compound semiconductor layer containing at least P as a group V element; a third semiconductor layer of a second conductivity type side located above the second semiconductor layer; an active layer disposed between the second semiconductor layer and the third semiconductor layer; a window structure formed across the third semiconductor layer, the active layer, the second semiconductor layer, and the first semiconductor layer; a defect layer comprising a defect, the defect layer being located in a region in which the window structure is formed and between the first semiconductor layer and the second semiconductor layer, the defect layer containing a group III material of the first semiconductor layer and a group III material of the second semiconductor layer; and an end surface which emits laser light, the end surface comprising a surface of the defect layer. The semiconductor laser element satisfies Equation (1):

y≥2.31×10⁻⁵x²−5.37×10⁻²x+4.44 (1)
where x (°) is a divergence angle of a far-field pattern of the laser light emitted from the semiconductor laser element in the direction from the first semiconductor layer to the active layer, and y (μm) is a thickness of the second semiconductor layer.

According to one aspect of the present disclosure, a semiconductor laser element having an improved lifetime can be provided.

### BRIEF DESCRIPTION OF DRAWINGS

FIG. 1 is a sectional view of a semiconductor laser element of a first embodiment.

FIG. 2 is an enlarged view of a window structure of the semiconductor laser element of the first embodiment in the vicinity of an interface between a first semiconductor layer and a second semiconductor layer.

FIG. 3 is a STEM image showing an example of the vicinity of a defect layer;

FIG. 4 is a sectional view of a semiconductor laser element of a second embodiment.

FIG. 5 is an enlarged view of a window structure of the semiconductor laser element of the second embodiment in the vicinity of an interface between a first semiconductor layer and a second semiconductor layer.

FIG. 6 is a sectional view of a semiconductor laser element of a modification of the second embodiment.

FIG. 7 is a sectional view of a semiconductor laser element of a third embodiment;

FIG. 8 is a graph showing failure rates of the semiconductor laser elements of Example 1 and Example 2.

FIG. 9 is a graph showing failure rates of the semiconductor laser elements of Comparative Example 1.

FIG. 10 is a graph showing a relationship between the thickness of a defect layer and FFPy.

### DETAILED DESCRIPTION

Hereinafter, embodiments of the present invention will be described in detail. The following embodiments exemplify a semiconductor laser element for embodying the technical idea of the present invention. The present invention is not limited to the following semiconductor laser elements.

In the present specification, a stacking direction of semiconductor layers is referred to as a thickness direction. An optical axis direction of an optical waveguide is referred to as a longitudinal direction. A direction perpendicular to the thickness direction and the longitudinal direction is referred to as a lateral direction.

### First Embodiment

### <Semiconductor Laser Element 100>

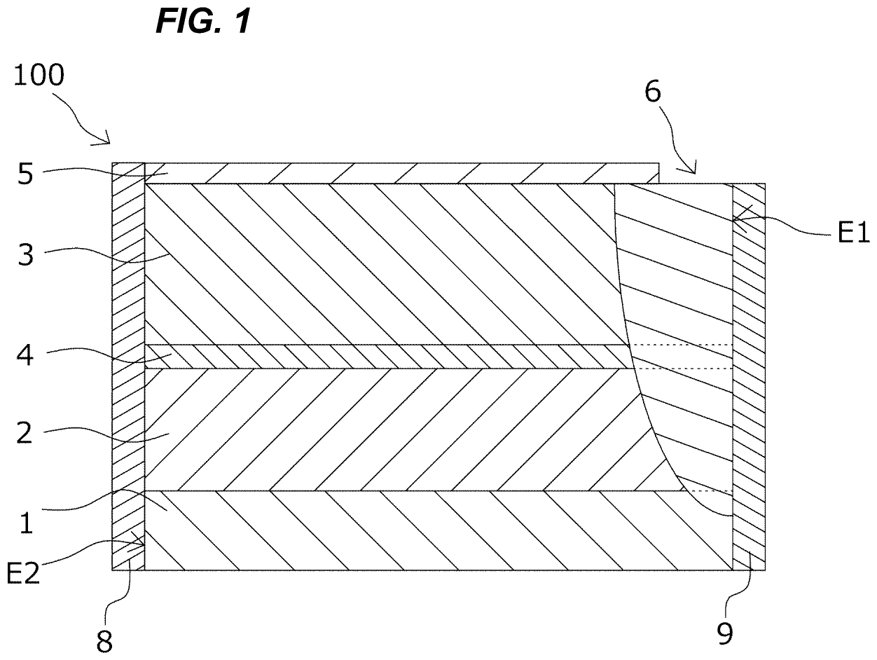

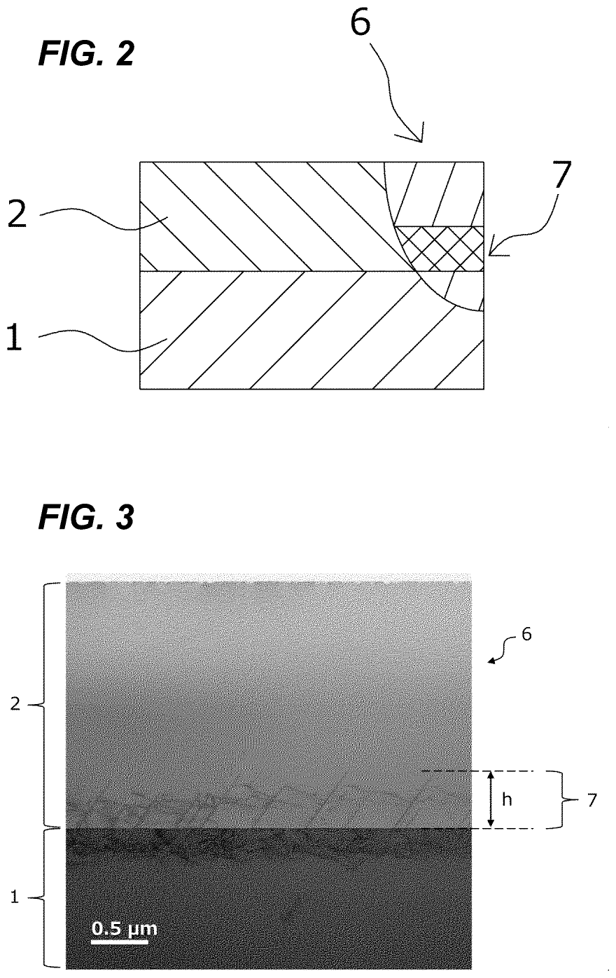

First, a semiconductor laser element 100 of a first embodiment will be described with reference to FIGS. 1 and 2. A semiconductor laser element 100 of the present disclosure comprises: a first semiconductor layer 1 that is a III-V group compound semiconductor layer containing at least As as a group V element; a second semiconductor layer 2 of a first conductivity type side located above the first semiconductor layer, the second semiconductor layer being a III-V compound semiconductor layer containing at least P as a group V element; a third semiconductor layer 3 of a second conductivity type side located above the second semiconductor layer 2; an active layer 4 disposed between the second semiconductor layer 2 and the third semiconductor layer 3; and a window structure 6 formed across the third semiconductor layer 3, the active layer 4, the second semiconductor layer 2, and the first semiconductor layer 1. The semiconductor laser element 100 of the present disclosure comprises a defect layer 7 comprising a defect. The defect layer 7 is located in a region in which the window structure 6 is formed, and located between the first semiconductor layer 1 and the second semiconductor layer 2. The defect layer 7 contains a group III material of the first semiconductor layer 1 and a group III material of the second semiconductor layer 2. The semiconductor laser element 100 also comprises an end surface E1 which emits laser light. The end surface E1 comprises a surface of the defect layer 7. The defect layer 7 does not overlap with a near-field pattern of the laser light at the end surface E1, or overlaps only with a tail of the near-field pattern at the end surface E1.

This can provide a semiconductor laser element having an improved lifetime.

Examples of the semiconductor used in the semiconductor laser element that emits red or infrared laser light include a III-V compound semiconductor in which the group V element is As or P. The III-V compound semiconductor in which the group V element is As and the III-V compound semiconductor in which the group V element is P can realize lattice matching by adjusting the composition ratio of the group III element. For example, a lattice of GaAs and a lattice of AlGaInP having an In composition ratio of around 0.5 are lattice-matched. However, when impurities are diffused to form the window structure 6, mutual diffusion of indium (In), aluminum (Al), and gallium (Ga) occurs between an arsenic (As)-based compound semiconductor and a phosphorus (P)-based compound semiconductor. As a result, in the vicinity of the interface between the As-based compound and the P-based compound that have been lattice matched with GaAs, the composition ratio of the group III changes, which causes lattice mismatch with GaAs, and the thickness exceeds a critical film thickness, thereby generating a crystal defect. This defect obtains light energy of the laser light when overlapping with the laser light, and extends toward the active layer 4 during driving. When the defect extends, the proportion of the defect overlapping with the laser light also increases, and the laser light is easily absorbed. It is considered that the defect generates heat by absorbing the laser light, and COD is generated.

Thus, reduction of the overlap between the defect and the laser light as much as possible improves the COD level, which contributes to obtaining a semiconductor laser element whose sudden death caused by COD is reduced.

Each configuration of the semiconductor laser element 100 will be described with reference to FIGS. 1 and 2. FIG. 1 is a sectional view of the semiconductor laser element 100 of the first embodiment. FIG. 1 is a sectional view taken along a resonator direction (that is, the longitudinal direction). FIG. 2 is an enlarged view of the window structure 6 of the semiconductor laser element 100 of the first embodiment in the vicinity of an interface between the first semiconductor layer 1 and the second semiconductor layer 2.

### (First Semiconductor Layer 1)

The first semiconductor layer 1 includes one or more III-V semiconductor layers containing As. The first semiconductor layer 1 may be, for example, GaAs, AlGaAs, InGaAs, AlInAs, or AlGaInAs. Arsenide (As) is not an impurity but forms a part of the composition of the semiconductor layer constituting the first semiconductor layer 1. The first semiconductor layer 1 may be a semiconductor layer of the first conductivity side having one or more layers containing impurities of a first conductivity type. The first conductivity type may be n-type. The impurity of the first conductivity type may be, for example, silicon (Si), carbon (C), germanium (Ge), tin (Sn), or tellurium (Te). The thickness of the first semiconductor layer 1 may be, for example, 0.01 μm or more and 0.1 μm or less.

### (Second Semiconductor Layer 2)

The second semiconductor layer 2 is a III-V semiconductor layer containing P. The second semiconductor layer is formed on the first semiconductor layer 1. The second semiconductor layer 2 may be a semiconductor layer of the first conductivity side having one or more layers containing impurities of the first conductivity type. The impurity of the first conductivity type may be, for example, Si, C, Ge, Sn, or Te. The second semiconductor layer 2 may be, for example, InGaP, AlGaInP, or AlInP. P is not an impurity but forms a part of the composition of the semiconductor layer constituting the second semiconductor layer 2.

The second semiconductor layer 2 includes at least a cladding layer and confines light in the active layer 4. The thickness of the second semiconductor layer 2 is, for example, 1 μm or more and 4 μm or less. With this configuration, the active layer 4 can be positioned away from the defect layer 7. Thus, it is possible to reduce the overlap between the near-field pattern and the defect layer 7 on the end surface E1 from which the laser light is emitted.

### (Third Semiconductor Layer 3)

The third semiconductor layer 3 is a semiconductor layer disposed on the second semiconductor layer 2. The third semiconductor layer 3 may be a semiconductor layer of the second conductivity side having one or more layers containing impurities of a second conductivity type different from the first conductivity type. The impurity of the second conductivity type may be, for example, magnesium (Mg), zinc (Zn), or C. The third semiconductor layer 3 is, for example, a III-V semiconductor containing P or As. The third semiconductor layer 3 may be, for example, GaP, InGaP, AlInP, or AlGaInP.

The third semiconductor layer 3 includes at least a cladding layer and confines light in the active layer 4. The thickness of the third semiconductor layer 3 is, for example, 0.5 μm or more and 2 μm or less.

### (Active Layer 4)

The active layer 4 is disposed between the second semiconductor layer 2 and the third semiconductor layer 3. The active layer 4 has a quantum well structure, and the structure may be a single quantum well structure including one well layer and a plurality of barrier layers, or may be a multiple quantum well structure including a plurality of well layers and a plurality of barrier layers. The well layer may be, for example, InGaP, AlGaInP, InGaAsP, AlGaInAsP, or AlInAsP. The barrier layer may be, for example, InGaP, AlGaInP, InGaAsP, AlGaInAsP, or AlInAsP. The semiconductor laser element may have one or more or two or more light emission points. When there are a plurality of light emission points, light of the same color is emitted from the light emission points. That is, only red light or only infrared light is emitted from the semiconductor laser element.

### (Window Structure 6)

The window structure 6 is disposed across the third semiconductor layer 3, the active layer 4, the second semiconductor layer 2, and the first semiconductor layer 1. The window structure 6 is provided in the end surface E1 and a region in the vicinity of the end surface E1. The window structure 6 has a band gap energy larger than the energy corresponding to the wavelength of the laser light emitted from the end surface E1. The window structure 6 is formed by, for example, diffusion of zinc (Zn) or interdiffusion of group III elements via vacancies.

### (Defect Layer 7)

The defect layer 7 includes a defect. The defect layer 7 is in the window structure 6 and located between the first semiconductor layer 1 and the second semiconductor layer 2. The defect layer 7 contains a group III material of the first semiconductor layer 1 and a group III material of the second semiconductor layer 2. A start point of the defect is an interface between the first semiconductor layer 1 and the second semiconductor layer 2. The defect layer 7 may be formed due to formation of the window structure 6.

That is, it is considered that the defect layer 7 may be generated through diffusion of the group III elements contained in the first semiconductor layer 1 and the group III elements contained in the second semiconductor layer 2 with each other in the process of forming the window structure 6. Normally, the semiconductor layer containing As and the semiconductor layer containing P can be lattice-matched by setting the composition ratio of In to around 0.5, and defects are unlikely to be generated. However, in the semiconductor laser element 100 of the first embodiment, during the process of forming the window structure 6, for example, Zn is diffused or group III elements are interdiffused via vacancies. At this time, Ga, Al, and In also diffuse, and the compositions of the first semiconductor layer 1 and the second semiconductor layer 2 change, resulting in a lattice mismatch state. In the lattice mismatch state, a defect is generated at the interface between the first semiconductor layer 1 and the second semiconductor layer 2 because of the distortion caused by a difference in lattice constant. The defect includes at least a linear defect (that is, a dislocation).

The defect layer 7 is, for example, a layer containing Ga, Al, and In. The thickness of the defect layer may be, for example, 0.01 μm or more and 1.5 μm or less. The thickness of the defect layer is measured in the direction from the interface between the first semiconductor layer 1 and the second semiconductor layer 2 toward the active layer. In a sectional view as shown in FIG. 1, the defects containing the defect layer 7 extend from the interface between the first semiconductor layer 1 and the second semiconductor layer 2. The defects can be observed with a scanning transmission electron microscope (STEM). In the present specification, the thickness of the defect layer 7 corresponds to a distance between the interface of the first semiconductor layer 1 and the second semiconductor layer 2 and a tip of the defect that is closest to the active layer among tips of the defects within the defect layer 7. Specific method for measuring the thickness of the defect layer 7 includes: obtaining a STEM image containing the defect layer; selecting a measurement region from the obtained STEM image; and determining the defect that extends closest to the active layer 4, among the defects extending from the interface between the first semiconductor layer 1 and the second semiconductor layer 2 in the measurement region. The determined defect is referred to as “a measured defect.” A distance between a tip of the measured defect and the interface is the thickness of the defect layer 7. The STEM image is obtained at a magnification of 10,000× to 60,000×, with the interface oriented approximately in the horizontal direction. The measurement region is selected to include the measured defect and has a horizontal dimension of, for example, 3 μm.

FIG. 3 is a STEM bright-field image showing an example of the vicinity of the defect layer 7. FIG. 3 shows that it can be seen that the defect extends toward the active layer 4 starting from the interface between the first semiconductor layer 1 and the second semiconductor layer 2, that is, the interface between the As-based III-V semiconductor and the P-based III-V semiconductor. In this example, the thickness h of the defect layer is about 0.6 μm.

The defect layer 7 is generated by forming the window structure 6 as described above. Thus, when diffusion of Zn or interdiffusion of group III elements via vacancies does not extend to the vicinity of the interface between the first semiconductor layer 1 and the second semiconductor layer 2, lattice matching of these layers is maintained, and the defect layer 7 is not generated. However, in the semiconductor laser element of the present embodiment, the defect layer 7 is formed along with the formation of the window structure 6. This is to improve the COD level by diffusing the Zn or interdiffusing group III elements via vacancies to an area including the vicinity of the interface to form the window structure 6. In addition, as described later, the far-field pattern can be narrowed by widening the near-field pattern.

### (Near-Field Pattern)

The near-field pattern (NFP) reflects the shape of the laser light propagating through the optical waveguide. Because the core is located between the claddings in the optical waveguide, most of the laser light is confined in the core. On the other hand, confinement of the laser light is weakened in the portion of the window structure 6. The NFP in the region where the window structure 6 is formed is larger than that in the optical waveguide where the window structure 6 is not formed. In particular, NFP is the largest at the end surface E1.

In the semiconductor laser element 100 of the first embodiment, the defect layer 7 does not overlap with a near-field pattern of the laser light at the end surface E1, or overlaps only with a tail of the NFP at the end surface E1. This makes it difficult for the defect to receive the optical energy of the laser light. Thus, the defect hardly extends toward the active layer 4, and the COD level of the semiconductor laser element 100 is improved. To confirm the overlap between the NFP and the defect layer 7, the tail of the NFP may be determined based on the line profile in the thickness direction of the NFP, in a cross section view of the region including the core of the optical waveguide.

In the present specification, the tail of the NFP means a region outside the beam spot determined by a diameter of the NFP. The beam diameter is defined by D4σ. D4σ matches the beam diameter defined by 1/e² when the line profile of the beam has an ideal Gaussian. In order to confirm whether or not the NFP and the defect layer 7 overlap and to what degree they overlap, it is sufficient to consider only the line profile of the NFP in the thickness direction.

The NFP can be measured without directly observing the shape on the end surface E1. As will be described later, after the laser light is emitted from the end surface E1, the NFP changes to a far-field pattern (FFP) because of the effect of diffraction. The FFP is in the relationship of the Fourier transform of the NFP. Thus, through the inverse Fourier transform on the FFP using a convex lens, the shape of the NFP can be reproduced at a position away from the end surface E1. The size of the reproduced NFP image can be measured, and the distance from the lens to the image and the rear focal length of the lens are known. Thus, the size of the NFP on the end surface E1 can be calculated by using the definition formula of the lateral magnification. Because the dimension of the semiconductor laser element 100 and the position of the defect layer 7 on the end surface E1 are also known, it can be evaluated whether or not the NFP and the defect layer 7 overlap, and to what degree they overlap. The image of the NFP can be obtained by using, for example, collimated light measurement optical system M-Scope type C manufactured by Synos.

The defect layer 7 may overlap with the end surface E1 only at the tail of the NFP. The defect layer 7 preferably overlaps with the NFP only in a region in which the area of the NFP from the end of the NFP is 0.025% or less. In other words, the defect layer 7 does not overlap with the NFP in a central region in which the area is 49.975% (=50-0.025%) from the center of the NFP, and the defect layer 7 and the NFP are permitted to overlap with each other outside the central region. The area of the NFP is a proportion when the area estimated from the line profile of the NFP in the thickness direction is 100%. The end of the NFP represents a position where the value indicated by the line profile is substantially zero. The area at the tail of the NFP is relatively small. As a result, the area in which the defect layer 7 overlaps with the tail of the NFP is relatively small, and the COD level can be increased. Such an evaluation can also be performed, similarly to the method described above, by obtaining the image of the NFP using collimated light measurement optical system M-Scope type C, manufactured by Synos, and overlaying the image on the defect layer.

### (Far-Field Pattern)

The Far-field pattern (FFP) is a diffraction pattern of NFP. FFP is normally represented by a divergence angle in the lateral direction (FFPx) and a divergence angle in the thickness direction (FFPy). These divergence angles are determined based on full width at half maximum, in other words, full angular width at half maximum.

As described above, FFP is a diffraction pattern of NFP, and FFP and NFP are in correspondence with each other. When the NFP in the thickness direction is small (that is, when optical confinement is relatively strong), the angle of the FFP in the thickness direction increases. On the other hand, when the NFP in the thickness direction is large (that is, when optical confinement is relatively weak), the angle of the FFP in the thickness direction decreases.

The optical confinement in the thickness direction of the semiconductor laser element is realized by a stack structure of semiconductor layers, and it is considered that the single mode condition is almost satisfied in the thickness direction. Thus, assuming that the FFP can be approximated by a Gaussian, the inventor has considered that a structure in which the defect layer 7 is positioned away from the NFP can be derived by using the FFP instead of the NFP. To verify this hypothesis, the following experiments and simulations were performed.

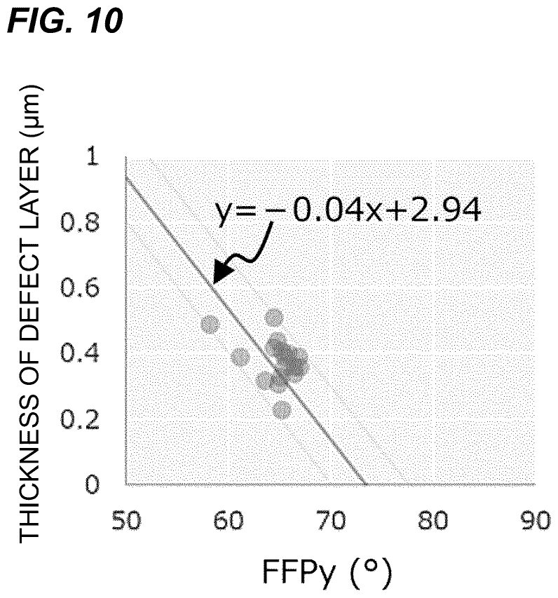

A plurality of semiconductor laser elements including an n-side cladding layer having a thickness of 0.9 μm and a window structure with FFPy in a range of about 55° to about 70° were produced, and the relationship between the failure rate and FFPy was examined. The failure rate tended to decrease as FFPy increases. Based on the obtained results, the failure rate was significantly reduced when FFPy was more than about 60°. The failure rate is expressed by [the number of semiconductor laser elements that died suddenly within 200 hours when a current having a current density of 3826 A/cm² was input to the semiconductor laser elements]÷[the number of tested semiconductor laser elements]×100(%). Under these conditions, 200 hours is equivalent to 1000 hours in a normal test. That is, the failure rate is measured under acceleration test conditions. In addition, as a result of measuring the thickness of the defect layer for these semiconductor laser elements and examining the relationship between the failure rate and the thickness, it has been found that the failure rate tends to increase as the thickness of the defect layer increases. The threshold of the thickness of the defect layer at which the failure rate began to increase was about 0.3 μm. Based on these results, a plot was made with FFPy (°) on the horizontal axis (that is, the x axis) and the thickness (μm) of the defect layer on the vertical axis (that is, the y axis). When the plotted data were fitted with a linear function, an approximate equation y=−0.04x+2.94 was obtained. The results are shown in FIG. 10.

When the FFP was assumed to followed a Gaussian, the NFP that could reproduce the obtained FFPy was simulated; that is, the NFP was simulated based on the measured FFPy. Then, the overlap between the NFP and the defect layer was examined. When the angle (°) of FFPy, the thickness (μm) of the defect layer, and the percentage (%) of light overlapping with the defect layer are combined and shown in parentheses, they are (45.7°, 1.107 μm, 67.09%), (49.7°, 0.947 μm, 38.54%), (52.3°, 0.843 μm, 19.88%), (56.1°, 0.691 μm, 4.67%), (58.3%, 0.603 μm, 1.62%), (62.9°, 0.419 μm, 0.14%), and (66.9°, 0.259 μm, 0.01%). The thickness of the defect layer was obtained from the approximate equation y=−0.04x+2.94 shown in FIG. 10. The percentage of light overlapping with the defect layer represents the percentage of light overlapping with the defect layer to the total area of the line profile of the simulated NFP.

Three data points, each having FFPy of 58.3°, 62.9°, and 66.9°, respectively, were plotted against the thickness of the defect layer and the percentage of light overlapping with the defect layer. Three data points were selected so that the FFPy range determined by them would include the estimated threshold of 60° and its vicinity. Then the plotted data points were fitted with an exponential function based on the Napier's constant e. They were able to be approximated by y=4×10⁻⁴×e^{13.865x}, where x (μm) is the thickness of the defect layer, and y (%) is the percentage of light overlapping with the defect layer. When the threshold of the thickness of 0.3 μm is substituted for x in this approximate equation, it can be estimated that the overlap between the NFP and the defect layer is about 0.025%.

On the NFP, a specific position was determined such that an area of the NFP between the center of the NFP and the specific position is 49.975(%) (=50-0.025) of the total area of NFP. The specific position also means to a position of an edge of an overlapping region between the defect layer and the NFP when an area of the overlapping region is 0.025% of the total area of the NFP.

The distance between the center of the NFP and the specific position for each semiconductor laser element obtained was measured and plotted with FFPy (°) on the horizontal axis (that is, the x axis) and the distance (μm) as measured on the vertical axis (that is, the y axis).
When the plotted data were fitted with a quadratic function, an approximate equation y=2.31×10⁻⁵x²−0.0137x+1.5082 was obtained.

The sum of the two approximate equations of y=−0.04x+2.94 and y=2.31×10⁻⁵x²-0.0137x+1.5082 is the sum of “the thickness of the defect layer” and “the distance between the center of the NFP and the specific position (that is, the distance between the center of the NFP and the position of the edge of the overlapping region between the defect layer and the NFP when the area of the overlapping region is 0.025%).” Thus, the sum is an approximate equation representing the desired thickness of the second semiconductor layer 2, which is expressed by Equation (1) shown below.

Based on the above examination, Equation (1) shown below was obtained. That is, regarding the laser light emitted from the semiconductor laser element 100, Equation (1) shown below is desirably satisfied:

y≥2.31×10⁻⁵x²−5.37×10⁻²x+4.44 (1)
where x is a divergence angle (°) of an FFP of the laser light in the direction from the first semiconductor layer 1 to the active layer 4 (that is, the thickness direction), and y is a thickness (μm) of the second semiconductor layer 2.

When the thickness (y) of the second semiconductor layer 2 is equal to the value indicated on the right side of Equation (1), the area of the overlapping region between the defect layer and the NFP is 0.025%. When the thickness (y) of the second semiconductor layer 2 is larger than the value indicated on the right side of Equation (1), the overlapping region between the NFP and the defect is reduced. According to Equation (1), it can be seen that the desired thickness of the second semiconductor layer 2 varies depending on the divergence angle of the FFP in the thickness direction. FFPy (that is, x in Equation (1)) may be 45° or more and 70° or less and 50° or more and 60° or less. For example, when x is 50°, y is 1.81 μm or more. When x is 60°, y is 1.30 μm or more.

When the thickness of the second semiconductor layer 2 is too large, the resistance component increases, and the forward voltage (Vf) at the time of driving the semiconductor laser element increases. Thus, the thickness can be appropriately set so that Vf does not excessively increase. The thickness of the second semiconductor layer 2 may be 4 μm or less, for example. The thickness of the second semiconductor layer 2 may be, preferably, 2 μm or less. This can further reduce the increase in Vf.

The thickness of the second semiconductor layer 2 may satisfy Equation (1) as well as may be 4 μm or less. Specifically, the thickness of the second semiconductor layer 2 may be 1 μm or more and 4 μm or less, and preferably 1 μm or more and 2 μm or less. This can reduce the overlap between the defect layer 7 and the NFP to improve the COD level and obtain the semiconductor laser element 100 whose sudden death caused by COD is reduced. Further, it is possible to reduce an increase in Vf when the semiconductor laser element is driven.

### (Distance Between Active Layer 4 and Defect Layer 7)

The distance from the active layer 4 to the defect layer 7 is 0.5 μm or more and 3 μm or less, preferably 2 μm or more and 2.5 μm or less. This can reduce the overlap between the defect layer 7 and the NFP to improve the COD level and obtain the semiconductor laser element 100 whose sudden death caused by COD is reduced.

### (Relationship Between Thicknesses of Second Semiconductor Layer 2 and Defect Layer 7)

The thickness of the second semiconductor layer 2 is twice or more and four times or less the thickness of the defect layer 7. When the thickness of the second semiconductor layer 2 is sufficiently larger than the thickness of the defect layer 7, the overlap between the defect layer 7 and the NFP can be reduced. When the defect included in the defect layer 7 extends obliquely, the length of the defect is evaluated by the length in the thickness direction.

### (Fourth Semiconductor Layer 5)

A fourth semiconductor layer 5 is a contact layer. The fourth semiconductor layer 5 is connected to an electrode. The fourth semiconductor layer 5 may be, for example, GaAs, AlGaAs, or GaP.

### (Lateral Mode)

The semiconductor laser element 100 of the first embodiment can oscillate in multiple modes. This can improve the power of the laser light. The number of modes of the lateral mode can be controlled by the lateral width of the optical waveguide.

### (Antireflection Coating 9)

An antireflection coat 9 may be disposed on the end surface E1. This can efficiently extract the laser light. The antireflection coating 9 is a dielectric multilayer film, and may be a multilayer film comprising, for example, at least two types of layers selected from SiO₂, Al₂O₃, and Ta₂O₅. The reflectance of the antireflection coating 9 at the wavelength of the laser light may be, for example, 5% or more and 15% or less.

### (Highly Reflective Coating 8)

To efficiently perform resonance, a highly reflective coating 8 may be disposed on an end surface E2 opposite to the end surface E1 from which laser light is emitted. This can efficiently resonate light. The highly reflective coating 8 is a dielectric multilayer film, and may be multilayer films comprising, for example, at least two types of layers selected from SiO₂, Ta₂O₃, and Al₂O₃. The reflectance of the highly reflective coating 8 at the wavelength of the laser light may be, for example, 90% or more and 100% or less.

### Modification of First Embodiment

As described above, NFP is associated with FFP. Thus, the thickness required for the second semiconductor layer 2 can be specified from the divergence angle of the FFP in the thickness direction without obtaining the NFP. Thus, the semiconductor laser element may have a configuration of the following modification.

The semiconductor laser element comprises: a first semiconductor layer 1 that is a III-V group compound semiconductor layer containing at least As as a group V element; a second semiconductor layer 2 of a first conductivity type side located above the first semiconductor layer 1, the second semiconductor layer 2 being a III-V compound semiconductor layer containing at least P as a group V element; a third semiconductor layer 3 of a second conductivity type side, located on the second semiconductor layer 2; an active layer 4 disposed between the second semiconductor layer 2 and the third semiconductor layer 3; a window structure 6 formed across the third semiconductor layer 3, the active layer 4, the second semiconductor layer 2, and the first semiconductor layer 1; a defect layer 7 comprising a defect, the defect layer 7 being located in a region in which the window structure 6 is formed and between the first semiconductor layer 1 and the second semiconductor layer 2, the defect layer 7 containing a group III material of the first semiconductor layer 1 and a group III material of the second semiconductor layer 2; and an end surface E1 which emits laser light, the end surface E1 comprising the defect layer 7. The semiconductor laser element satisfies y≥2.31×10⁻⁵x²−5.37×10⁻²x+4.44 . . . (1), where x (°) is a divergence angle of a far-field pattern of the laser light emitted from the semiconductor laser element in the direction from the first semiconductor layer 1 to the active layer 4, and y (μm) is a thickness of the second semiconductor layer 2.

This allows for improving the COD level and obtaining a semiconductor laser element whose sudden death caused by COD is reduced.

### Second Embodiment

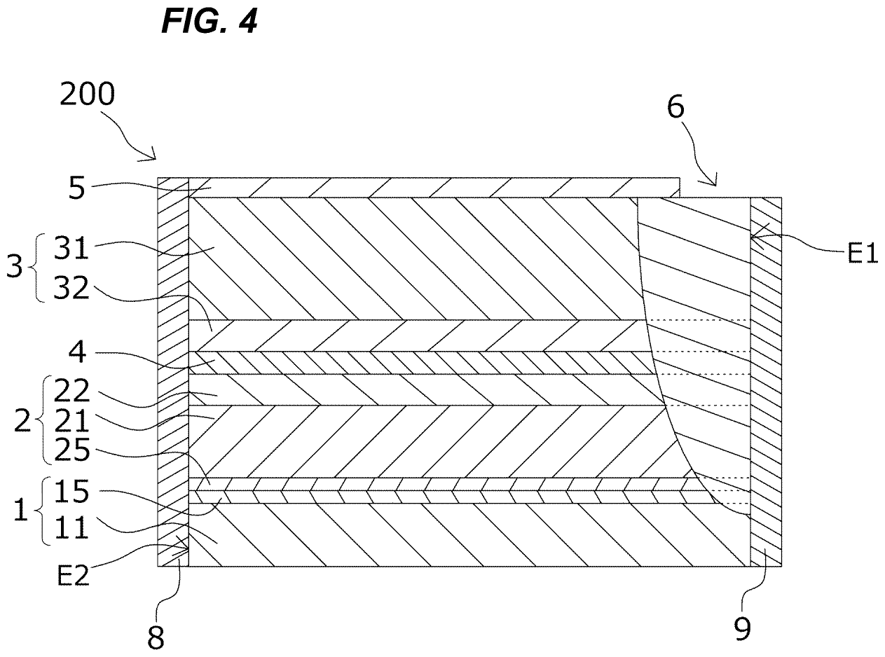

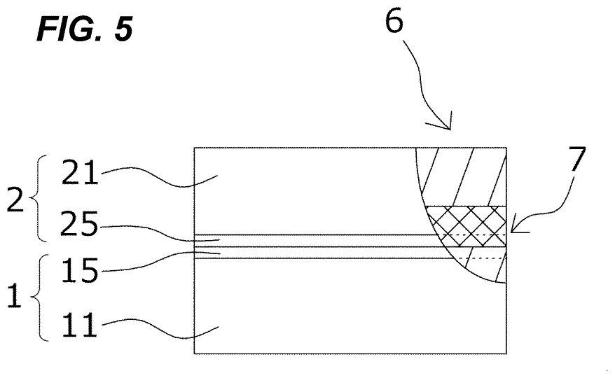

FIGS. 4 and 5 show a semiconductor laser element 200 of the second embodiment. A semiconductor laser element 200 of a second embodiment is different from the semiconductor laser element 100 of the first embodiment in the following points. The first semiconductor layer 1 includes a substrate 11 and a first band discontinuous relaxation layer 15 (first BDR layer 15), and the second semiconductor layer 2 includes a second band discontinuous relaxation layer 25 (second BDR layer 25), an n-side cladding layer 21, and an n-side light guide layer 22. Third semiconductor layer 3 includes a p-side light guide layer 32 and a p-side cladding layer 31. The semiconductor laser element of the present embodiment is different from the semiconductor laser element 100 of the first embodiment in these points. This enables efficiently confining light in the thickness direction and efficiently perform laser oscillation.

The configuration of the semiconductor laser element 200 of the second embodiment will be described with reference to FIGS. 4 and 5. Hereinafter, only changes from the first embodiment will be described. FIG. 4 is a sectional view of the semiconductor laser element 200 of the second embodiment. FIG. 4 is a sectional view taken along a resonator direction (that is, the longitudinal direction). FIG. 5 is an enlarged view of the window structure 6 of the semiconductor laser element 200 of the second embodiment in the vicinity of an interface between the first semiconductor layer 1 and the second semiconductor layer 2.

### (Substrate 11)

The first semiconductor layer 1 includes a substrate 11. The substrate 11 is a growth substrate of each semiconductor layer. The substrate 11 may be a GaAs substrate. The thickness of the substrate 11 may be, for example, 300 μm or more and 1000 μm or less.

### (First BDR Layer 15)

The first semiconductor layer 1 includes a first BDR layer 15. The first BDR layer 15 is disposed on the substrate 11. The first BDR layer 15 is a layer that alleviates discontinuity of a valence band and/or a conduction band occurring at a heterointerface of the semiconductor. The first BDR layer 15 may be, for example, AlGaAs or AlGaInAs. The thickness of the first BDR layer 15 may be, for example, 0.01 μm or more and 0.1 μm or less.

### (Second BDR Layer 25)

The second semiconductor layer 2 includes a second BDR layer 25. The second BDR layer 25 may be, for example, AlInP or AlGaInP. The thickness of the second BDR layer 25 may be, for example, 0.01 μm or more and 0.1 μm or less. In the second embodiment, an interface between the first BDR layer 15 and the second BDR layer 25 corresponds to an interface between the As-based III-V semiconductor layer and the P-based III-V semiconductor layer.

(n-Side Cladding Layer 21)

The second semiconductor layer 2 includes an n-side cladding layer 21. The n-side cladding layer 21 may be, for example, AlInP or AlGaInP. The thickness of the n-side cladding layer 21 may be, for example, 0.4 μm or more and 4 μm or less. The second BDR layer 25 is thinner than the n-side cladding layer 21. Because the second BDR layer 25 is thin, the defect is located not only in the second BDR layer 25 but also in the n-side cladding layer 21. That is, the defect layer reaches a part of the n-side cladding layer 21.

(n-Side Light Guide Layer 22)

The second semiconductor layer 2 includes an n-side light guide layer 22. The n-side light guide layer 22 may be, for example, AlInP or AlGaInP. The thickness of the n-side light guide layer 22 may be, for example, 0.02 μm or more and 0.3 μm or less.

(p-Side Light Guide Layer 32)

The third semiconductor layer 3 includes a p-side light guide layer 32. The p-side light guide layer 32 may be, for example, AlInP or AlGaInP. The thickness of the p-side light guide layer 32 may be, for example, 0.02 μm or more and 0.3 μm or less.

(p-Side Cladding Layer 31)

The third semiconductor layer 3 includes a p-side cladding layer 31. The p-side cladding layer 31 may be, for example, AlInP or AlGaInP. The thickness of the p-side cladding layer 31 may be, for example, 0.4 μm or more and 4 μm or less.

### (Third BDR Layer)

In the semiconductor laser element 200 of the second embodiment, a third BDR layer may be disposed on the third semiconductor layer 3. The third BDR layer may be, for example, AlInP or AlGaInP. The thickness of the third BDR layer may be, for example, 0.01 μm or more and 0.1 μm or less.

### (Inclination of Optical Axis of Laser Light at End Surface)

When the window structure 6 is formed, the disordering of the semiconductor layer occurs due to the diffusion of Zn or interdiffusion of group III elements via vacancies. The distribution of the refractive index in the vicinity of the interface between the first semiconductor layer 1 and the second semiconductor layer 2 and in the vicinity of the upper surface of the third semiconductor layer 3 is likely to change as compared with that before the window structure 6 is formed. The distribution of the refractive index after the window structure 6 is formed is asymmetric about the core of the optical waveguide as compared with the distribution of the refractive index before the window structure 6 is formed. The asymmetry of the distribution of the refractive index affects the emission angle of the laser light emitted from the end surface E1. Specifically, the optical axis of the laser light is inclined in the thickness direction with respect to the normal line of the end surface E1.

The influence of the asymmetry of the refractive index can be reduced by increasing the thickness of each cladding layer. This is because a region where the refractive index is asymmetric (that is, in the vicinity of the interface between the first semiconductor layer 1 and the second semiconductor layer 2 and in the vicinity of the upper surface of the third semiconductor layer 3) is positioned away from the core, and light is less affected by the refractive index of the region. Thus, the light is less affected by the region where the refractive index is asymmetric, and the inclination of the optical axis is improved. In the second embodiment, the thickness of the n-side cladding layer 21 may be 1.3 μm or more and 4 μm or less, and the thickness of the p-side cladding layer 31 may be 1.3 μm or more and 4 μm or less, such that the sufficient distances can be ensured from the core to the interface between the first semiconductor layer 1 and the second semiconductor layer 2, and to the upper surface of the third semiconductor layer 3. Although the refractive index distribution in the thickness direction becomes asymmetric by forming the window structure 6, the influence can be reduced, and the angle at which the optical axis of the laser light is inclined in the thickness direction with respect to the normal line of the end surface E1 can be reduced. The thicknesses of the n-side cladding layer 21 and the p-side cladding layer 31 are preferably 2 μm or less, and more preferably 1.5 μm or less. This makes it possible to reduce the inclination of the optical axis, while also reducing an increase in resistance due to an increase in the thickness of the semiconductor layer, thereby reducing an increase in Vf.

The absolute value of the angle formed by the optical axis of the laser light and the normal line of the end surface E1 in the thickness direction may be 0.01° or more and 0.95° or less, preferably 0.01° or more and 0.6° or less, and more preferably 0.01° or more and 0.3° or less. This can improve the inclination of the optical axis of the laser light and facilitate the combination of the laser light with the optical element disposed downstream on the optical axis of the semiconductor laser element. For example, it is easy to couple the laser light to the lens. In addition, it is easy to adjust the incident angle on the mirror.

### (Modification)

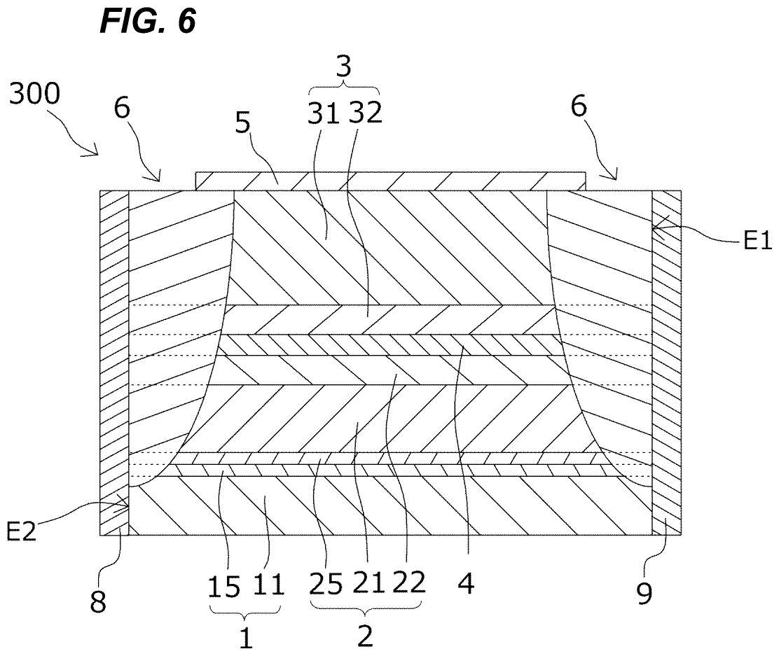

A modification of the semiconductor laser element 200 of the second embodiment will be described. Hereinafter, only changes from the second embodiment will be described. FIG. 6 is a sectional view of a semiconductor laser element 300 of the modification. FIG. 6 is a sectional view taken along a resonator direction (that is, the longitudinal direction). The semiconductor laser element 300 of the modification is different from the semiconductor laser element 200 of the second embodiment in that the window structures 6 are provided not only on the end surface E1 side but also on the end surface E2 side. In both of the window structures 6, the defect layer 7 as illustrated in FIG. 5 is formed in the vicinity of the interface between the first BDR layer 15 and the second BDR layer 25.

Similarly to the semiconductor laser element 200 of the second embodiment, the semiconductor laser element 300 of the modification has an improved COD level, thereby reducing sudden death caused by COD.

### Third Embodiment

A semiconductor laser element 400 of a third embodiment is different from the semiconductor laser element 200 of the second embodiment in the following points. The semiconductor laser element 400 is different from the semiconductor laser element 200 of the second embodiment in that the semiconductor laser element 400 is a single mode laser, and a diffraction grating is provided in the second semiconductor layer 2 or the third semiconductor layer 3. In the third embodiment, the semiconductor laser element 400 may be a distributed feedback laser element or a distributed Bragg reflection laser element. This enables obtaining laser light having a narrow spectral linewidth, the wavelength of which is selected by the diffraction grating.

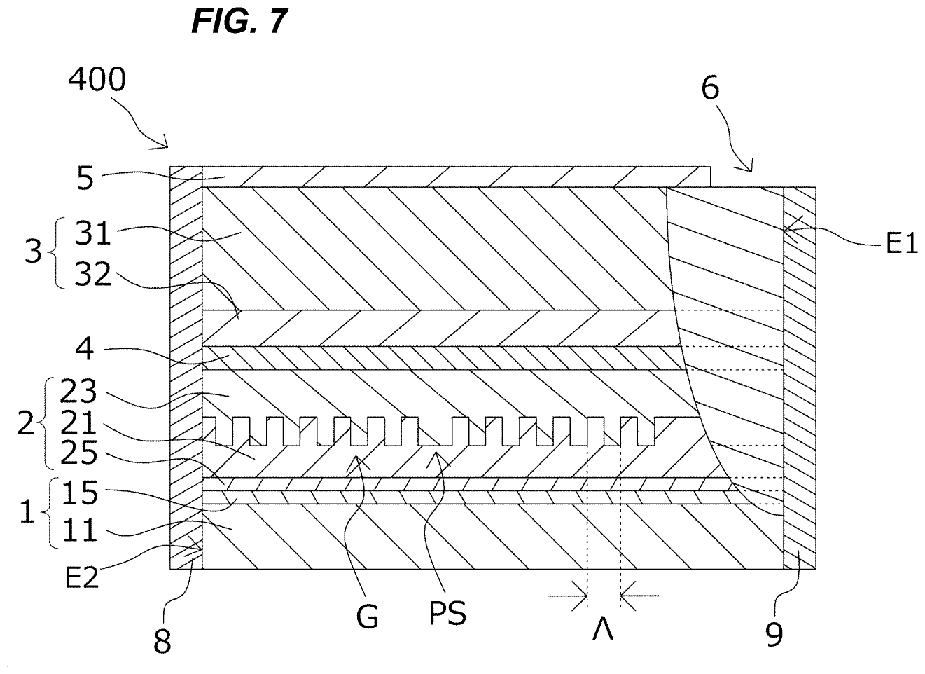

The configuration of the semiconductor laser element 400 of the third embodiment will be described with reference to FIG. 7. Hereinafter, only changes from the second embodiment will be described. FIG. 7 is a sectional view of the semiconductor laser element 400 of the third embodiment. FIG. 7 illustrates a section taken along a resonator direction (that is, the longitudinal direction).

### (Diffraction Grating)

As illustrated in FIG. 7, the semiconductor laser element 400 has a diffraction grating G at least in a portion where the window structure 6 is not provided. The diffraction grating G is provided in the second semiconductor layer 2 or the third semiconductor layer 3. In the example of FIG. 7, the diffraction grating G is provided in the second semiconductor layer 2 and has a periodic structure configured such that a plurality of protrusions of the n-side cladding layer 21 and a plurality of protrusions of the n-side light guide layer 22 are alternately arranged in the resonator direction. Assuming that the pitch of the diffraction grating G is Λ, the oscillation wavelength in vacuum is λ, and the equivalent refractive index of the stack structure in which the diffraction grating is formed is n_{eq}, the oscillation wavelength is expressed as λ=2×n_{eq}×Λ. The pitch Λ of the diffraction grating may be, for example, 100 nm or more and 500 nm or less. The diffraction grating G may include a phase shift structure PS. The phase shift structure PS may be a ¼ wavelength phase shift structure. This enables oscillation in a vertical single mode.

### EXAMPLES

Hereinafter, the present invention will be more specifically described with reference to Examples. The present invention is not limited to these Examples.

### Example 1

As Example 1, a plurality of semiconductor laser elements corresponding to the second embodiment were produced. The semiconductor laser element of Example 1 was obtained by forming a first BDR layer, a second BDR layer, an n-side cladding layer, an n-side light guide layer, an active layer, a p-side light guide layer, and a p-side cladding layer on a GaAs substrate by an MOCVD method. After the p-side cladding layer was formed, Zn was diffused to form a window structure at an end surface and a position in the vicinity of the end surface after cleavage. With the formation of the window structure, a defect layer was formed. The first BDR layer was an AlGaAs layer, and the second BDR layer was an AlGaInP layer. The interface between the first BDR layer and the second BDR layer is the interface between the III-V first semiconductor layer containing As and the III-V second semiconductor layer of the second conductivity side, the second semiconductor layer containing P. The total thickness of the second BDR layer, the n-side cladding layer, and the n-side light guide layer, that is, the thickness of the second semiconductor layer, was 2 μm. In the produced plurality of semiconductor laser elements, the diffusion amount of Zn for producing the window structure was adjusted such that FFPy of the laser light emitted from the semiconductor laser elements was in a range of about 45° to about 60°.

### Example 2

As Example 2, a plurality of semiconductor laser elements were produced. The semiconductor laser elements of Example 2 were different from the semiconductor laser elements of Example 1 in that the thickness of the second semiconductor layer was 1 μm, and FFPy was in a range of about 66° to about 70°, by adjusting the diffusion amount of Zn when the window structure was produced.

### Comparative Example 1

As Comparative Example 1, a plurality of semiconductor laser elements were produced. The semiconductor laser elements of Comparative Example 1 were different from the semiconductor laser elements of Example 1 in that the thickness of the second semiconductor layer was 1 μm, and FFPy was in a range of about 45° to about 65.9°, by adjusting the diffusion amount of Zn when the window structure was produced.

### (Failure Rate)

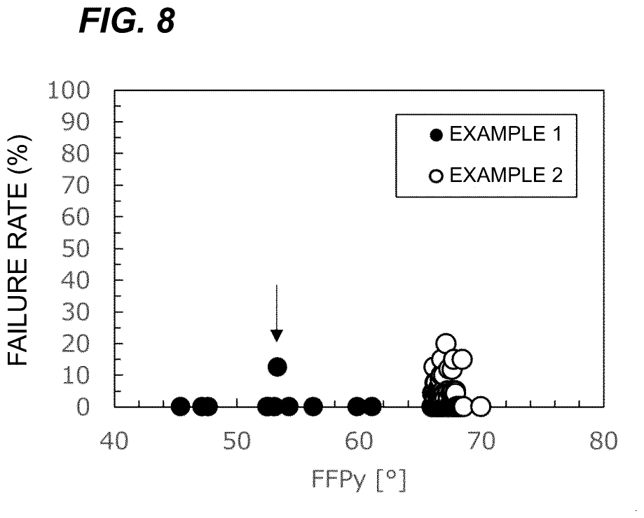

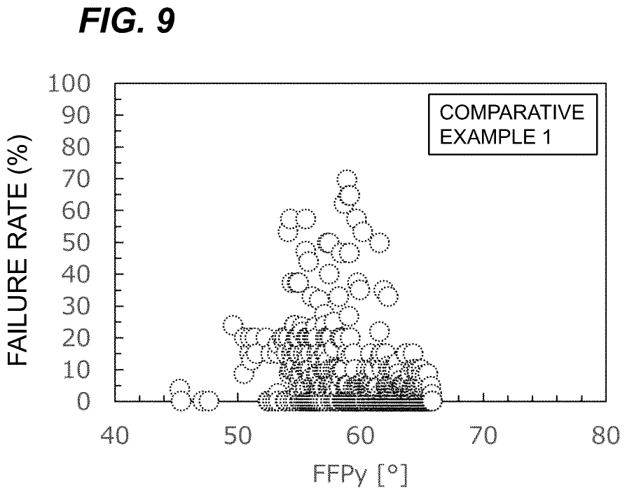

The failure rates of the semiconductor laser elements of Example 1, Example 2, and Comparative Example 1 were examined. FIG. 8 is a graph illustrating the failure rates of Example 1 and Example 2. In FIG. 8, filled circles indicate the results of Example 1, and hollow circles indicate the results of Example 2. FIG. 9 is a graph illustrating the failure rates of the semiconductor laser elements of Comparative Example 1. In FIGS. 8 and 9, the horizontal axis represents the angle of FFPy of the laser light emitted from each semiconductor las er element, and the vertical axis represents the failure rate. For ease of comparison, the same scales were set for the horizontal and the vertical axes in FIGS. 8 and 9.

In FIG. 8, the plot indicated by the arrow is a failure due to cleavage abnormality of the end surface and therefore can be ignored. The failure rate of the semiconductor laser elements of Example 1 except for this abnormality was 0%. Failure due to cleavage abnormality was not confirmed in the semiconductor laser elements of Example 2. The failure rate of the semiconductor laser elements of Example 2 was about 20% at the maximum.

As shown in FIG. 9, failure due to cleavage abnormality was not confirmed in the semiconductor laser elements of Comparative Example 1. FIG. 9 teaches that the failure rate of the semiconductor laser elements of Comparative Example 1 was about 70% at the maximum.

As for the failure rate, it was found that the results of Example 1 were significantly different from the results of Comparative Example 1. In particular, in the range of FFPy of 50° to 60°, there was a difference in failure rate even with almost the same value of FFPy. As the size of NFP in the thickness direction at the end surface increases, FFPy decreases due to diffraction. In other words, the smaller the FFPy, the larger the NFP in the thickness direction at the end surface. Thus, the results are considered to be because the thickness of the second semiconductor layer is 2 μm in Example 1, which is larger than the thickness of the second semiconductor layer in Comparative Example 1. It was presumed that the COD level was improved, and the sudden death was reduced because the defect layer does not overlap with the NFP at the end surface, or overlaps with the NFP only at a tail of the NFP at the end surface.

Similarly, the results of Example 2 tended to have a relatively low failure rate as compared with the results of Comparative Example 1. The thickness of the second semiconductor layer 2 is the same in Example 2 and Comparative Example 1, but FFPy is larger in Example 2 than in Comparative Example 1. As described above, the smaller the FFPy, the larger the NFP at the end surface, and thus the thickness of the second semiconductor layer required for reducing the overlap between the NFP and the defect layer 7 at the end surface is smaller in Example 2. Thus, it was presumed that the failure rate of Example 2 tended to be lower than that of Comparative Example 1 even when the thickness of the second semiconductor layer was the same.

The thickness of the second semiconductor layer 2 estimated from Equation (1) described above was compared with those in Example 1, Example 2, and Comparative Example 1. The preferable thickness of the second semiconductor layer, calculated using Equation (1), was about 1.3 μm or more when FFPy (that is, x in Equation (1)) was in a range of 45° to 60° from Equation (1). The preferable thickness of the second semiconductor layer was about 0.8 μm or more when FFPy was in a range of 66° to 70°. According to Equation (1), it can be seen that the smaller FFPy (that is, x in Equation (1)) is, the smaller the preferable thickness of the second semiconductor layer is. Based on these results, it was presumed that in the semiconductor laser elements of Examples 1 and 2, the second semiconductor layer was formed with a sufficient thickness. On the other hand, it was presumed that the thickness of the second semiconductor layer was insufficient in Comparative Example 1.

### Example 3

A semiconductor laser element of Example 3 was produced. As Example 3, a semiconductor laser element corresponding to the second embodiment was produced. The semiconductor laser element of Example 3 was obtained by forming a first BDR layer, a second BDR layer, an n-side cladding layer, an n-side light guide layer, an active layer, a p-side light guide layer, and a p-side cladding layer on a GaAs substrate by an MOCVD method. After the p-side cladding layer was formed, Zn was diffused to form a window structure at an end surface and a position in the vicinity of the end surface after cleavage. With the formation of the window structure, a defect layer was formed. The thickness of the n-side cladding layer was 1.9 μm, and the thickness of the p-side cladding layer was 1.4 μm.

### Comparative Example 2

A semiconductor laser element of Comparative Example 2 was produced. The semiconductor laser element of Comparative Example 2 is different from the semiconductor laser element of Example 3 in that the thicknesses of the n-side cladding layer and the p-side cladding layer are both 1 μm.

### (Inclination of Optical Axis)

The semiconductor laser elements of Example 3 and Comparative Example 2 were driven to examine the inclination of the optical axis of laser light. In Example 3, the absolute value of the angle between the optical axis of the laser light and the normal line of the end surface was 0.51°. In Comparative Example 2, the absolute value of the angle between the optical axis of the laser light and the normal line of the end surface was 0.98°. It was confirmed that the inclination of the optical axis of the semiconductor laser element of Example 3 was improved.

What is claimed is:

1. A semiconductor laser element comprising:
a first semiconductor layer that is a III-V group compound semiconductor layer containing at least As as a group V element;
a second semiconductor layer of a first conductivity type side located above the first semiconductor layer, the second semiconductor layer being a III-V compound semiconductor layer containing at least P as a group V element;
a third semiconductor layer of a second conductivity type side located above the second semiconductor layer;
an active layer disposed between the second semiconductor layer and the third semiconductor layer;
a window structure formed across the third semiconductor layer, the active layer, the second semiconductor layer, and the first semiconductor layer;
a defect layer comprising a defect, the defect layer being located in a region in which the window structure is formed and between the first semiconductor layer and the second semiconductor layer, the defect layer containing a group III element of the first semiconductor layer and a group III element of the second semiconductor layer; and
an end surface emitting a laser light, the end surface comprising a surface of the defect layer; wherein:
the defect layer does not overlap with a near-field pattern of the laser light at the end surface, or overlaps only with a tail of the near-field pattern at the end surface.

2. The semiconductor laser element according to claim 1, wherein:
the defect layer overlaps with the near-field pattern only in a range in which the area of the near-field pattern from an edge of the near-field pattern is 0.025% or less of the area of the near-field pattern.

3. The semiconductor laser element according to claim 1, wherein:
the semiconductor laser element satisfies Equation (1):
y≥2.31×10⁻⁵x²−5.37×10⁻²x+4.44 (1)
where x is a divergence angle (°) of a far-field pattern of the laser light in the direction from the first semiconductor layer to the active layer, and y is a thickness (μm) of the second semiconductor layer.

4. The semiconductor laser element according to claim 1, wherein:
the second semiconductor layer has a thickness of 1 μm or more and 3.5 μm or less.

5. The semiconductor laser element according to claim 1, wherein:
a distance between the active layer and the defect layer is 0.5 μm or more and 3 μm or less.

6. The semiconductor laser element according to claim 1, wherein:
a thickness of the second semiconductor layer is three times or more and ten times or less a thickness of the defect layer.

7. The semiconductor laser element according to claim 1, wherein:
the second semiconductor layer comprises an n-side cladding layer, and the third semiconductor layer comprises a p-side cladding layer.

8. The semiconductor laser element according to claim 7, wherein:
a thickness of the n-side cladding layer is 1.3 μm or more and 4 μm or less; and
a thickness of the p-side cladding layer is 1.3 μm or more and 4 μm or less.

9. The semiconductor laser element according to claim 1, wherein:
the first semiconductor layer comprises a substrate, and a band discontinuity relaxation layer located on the substrate, the substrate being a GaAs substrate, the band discontinuous relaxation layer comprising an AlGaAs layer;
the second semiconductor layer is an AlInP layer or an AlGaInP layer; and
the defect layer contains Al, In, and Ga.

10. The semiconductor laser element according to claim 1, wherein:
a thickness of the defect layer is 0.01 μm or more and 1.5 μm or less.

11. The semiconductor laser element according to claim 1, wherein:
Zn is distributed in the window structure.

12. The semiconductor laser element according to claim 1, wherein:
the semiconductor laser element is configured to oscillate in multiple modes.

13. A semiconductor laser element comprising:
a first semiconductor layer that is a III-V group compound semiconductor layer containing at least As as a group V element;
a second semiconductor layer of a first conductivity type side located above the first semiconductor layer, the second semiconductor layer being a III-V compound semiconductor layer containing at least P as a group V element;
a third semiconductor layer of a second conductivity type side located above the second semiconductor layer;
an active layer disposed between the second semiconductor layer and the third semiconductor layer;
a window structure formed across the third semiconductor layer, the active layer, the second semiconductor layer, and the first semiconductor layer;
a defect layer comprising a defect, the defect layer being located in a region in which the window structure is formed and between the first semiconductor layer and the second semiconductor layer, the defect layer containing a group III element of the first semiconductor layer and a group III element of the second semiconductor layer; and
an end surface emitting a laser light, the end surface comprising a surface of the defect layer; wherein:
the semiconductor laser element satisfies Equation (1):
y≥2.31×10⁻⁵x²−5.37×10⁻²x+4.44 (1)
where x is a divergence angle (°) of a far-field pattern of the laser light in the direction from the first semiconductor layer to the active layer, and y is a thickness (μm) of the second semiconductor layer.

14. The semiconductor laser element according to claim 13, wherein:
the second semiconductor layer has a thickness of 1 μm or more and 3.5 μm or less.

15. The semiconductor laser element according to claim 13, wherein:
a distance between the active layer and the defect layer is 0.5 μm or more and 3 μm or less.

16. The semiconductor laser element according to claim 13, wherein:
a thickness of the second semiconductor layer is three times or more and ten times or less a thickness of the defect layer.

17. The semiconductor laser element according to claim 13, wherein:
the second semiconductor layer comprises an n-side cladding layer, and the third semiconductor layer comprises a p-side cladding layer.

18. The semiconductor laser element according to claim 17, wherein:
a thickness of the n-side cladding layer is 1.3 μm or more and 4 μm or less; and
a thickness of the p-side cladding layer is 1.3 μm or more and 4 μm or less.

19. The semiconductor laser element according to claim 13, wherein:
the first semiconductor layer comprises a substrate, and a band discontinuity relaxation layer located on the substrate, the substrate being a GaAs substrate, the band discontinuous relaxation layer comprising an AlGaAs layer;
the second semiconductor layer is an AlInP layer or an AlGaInP layer; and
the defect layer contains Al, In, and Ga.

20. The semiconductor laser element according to claim 13, wherein:
a thickness of the defect layer is 0.01 μm or more and 1.5 μm or less.

21. The semiconductor laser element according to claim 4, wherein:
the semiconductor laser element is configured to oscillate in multiple modes.
